(19) United States
(12) Patent Application Publication
(10) Pub. No.: US 2012/0073635 A1
(43) Pub. Date: Mar. 29, 2012

(54) Tandem Dye-Sensitized Solar Cell and Method for Making Same

(76) Inventors: Jong-Jan Lee, Camas, WA (US); David R. Evans, Beaverton, OR (US); Karen Yuri Nishimura, La Center, WA (US); Sean Andrew Vail, Vancouver, WA (US); Wei Pan, Vancouver, WA (US)

(21) Appl. No.: 12/892,779

(22) Filed: Sep. 28, 2010

(51) Int. Cl. H01L 51/46; H01L 31/18; H01L 31/0256

(52) U.S. Cl. 136/255; 136/263; 438/74; 257/E31.126

(57) ABSTRACT

A method is provided for forming a tandem dye-sensitized solar cell (DSC) using a bonding process. The method forms a first photovoltaic (PV) cell including a cathode, a first dye, and an anode. A second PV cell is also formed including a cathode, a second dye, and an anode. The second PV cell anode is bonded to the first PV cell cathode, at a temperature of less than 100 degrees C., using a transparent conductive adhesive. In response to the bonding, an internal series electrical connection is formed between the first PV cell and the second PV cell. In one aspect, the second PV cell is formed from a first titanium oxide (TiO₂) nanotube (TNT) layer anode.

### BACKGROUND OF THE INVENTION

1. Field of the Invention

This invention generally relates to photovoltaic energy cells and, more particularly, to a tandem dye-sensitized solar cell (DSSC or DSC) formed by bonding a titanium oxide nanotube (TNT) layer at a low temperature.

2. Description of the Related Art

FIG. 1 is a partial cross-sectional view of typical DSC structure (prior art). DSCs had typically exhibited low conversion efficiencies until a breakthrough in 1991 by professor Grätzel and co-workers using a nanocrystalline titanium oxide (TiO₂) electrode modified with a photon absorbing dye. In modern DSC cells, the photoanode TiO₂ electrode is fabricated on a transparent conducting oxide (TCO), a monolayer of absorbed dye on a TiO₂ surface, a platinum (Pt) counter-electrode, and an electrolyte solution with a dissolved iodine ion/tri-iodide ion redox couple between the electrode. The structure shown in FIG. 1 has successfully demonstrated an energy conversion efficiency that exceeded 7% in 1991 (B. O'Regan and M. Gratzel, “A low cost high efficiency solar cell based on dye-sensitized colloidal TiO2 films,” Nature, 353, 737-740, Oct. 24, 1991) and 10% in 1993 (M. K. Nazeeruddin et al., J. Am. Chem. Soc., 115, 6382-6390, 1993). At the present, the highest reported efficiency to date is 11.1% (L. Han et al., “High efficiency of dye-sensitized solar cell and module,” IEEE 4^{th} World Conference on Photovoltaic Energy Conversion, 179-182, 1996).

In order to sensitize the TiO₂, a dye molecule is attached to the TiO₂ surface. When the dye molecule absorbs a photon, an electron is excited to the lowest unoccupied molecular orbital (LUMO) and is subsequently injected into the conduction band of the TiO₂. As a result of this, the dye molecule is transformed to its oxidized state. The injected electron percolates through the porous nanocrystalline structure to the TCO (negative electrode, anode) and finally through an external load to the counter electrode (positive electrode, cathode, and Pt). At the counter electrode, the electron is transferred to tri-iodide in the electrolyte to yield iodine (I₃₋+2ₑ₋→3I₋). The cycle is closed by reduction of the oxidized dye by the iodine in the electrolyte.

Dye-sensitized solar cells typically utilize a transparent, semiconducting, nanoparticle/nanoporous film as the photoanode. It is preferable that this nano-structured layer exhibit some sort of structural order so that electron transport is not hindered by scattering and reduced electron mobility. A nanotubular morphology is thus advantageous in providing an efficient pathway for electron transport while also promoting diffusion of the sensitizing dye over a large surface area.

Anodization of a Ti film in a fluoride-ion-containing electrolyte results in highly-ordered, vertically aligned nanotubular TiO2 morphology. The use of such TiO₂ nanotube (TNT) films has been widely documented in use in DSCs in the literature. However, several Obstacles exist in fabricating efficient DSCs with TNT:

Thick (greater than ˜10 micron (um)) TNT layers are preferred in order to maximize surface area over which the sensitizing dye can adsorb. However, it is difficult to deposit very dense, thick Ti films onto a substrate. It can take several hours to several days to deposit tens of microns of Ti and is thus not practical or cost-effective. Further, even if a thick Ti layer can be deposited onto the substrate, adhesion of the TNT layer to ITO/FTO is generally very poor and the TNT layer easily delaminates.

Another problem is that during anodization of Ti, a surface residue deposits onto the top of the TNT surface that is difficult to remove. If not removed, this residue can impede the diffusion and adsorption of sensitizing dye onto the nanotube surface area. While Ti foils can be anodized to form TNT films, any remaining unanodized foil is opaque and cannot be directly incorporated into a DSC without impeding light transmission. Alternatively, the TNT film itself can be easily removed from the foil, but transfer and application to a secondary substrate is difficult due to the fragility Of the freestanding TNT membrane and the lack of an appropriate transparent, electrically-conductive bonding adhesive.

In another aspect of solar cell technology, the most frequently explored strategy for achieving higher efficiency in solar cells has focused on the use of a tandem cell structure, through which individual cells can be tuned to a particular frequency of the spectrum. This allows the cells to be stacked such that layers capable of capturing shorter wavelengths are located on top, while longer wavelengths of light are allowed to pass through the top and travel to the lower layers. For DSC cells, several tandem cell concepts and structures have been proposed. One proposal suggests a random mixture of two or more dyes with different absorption spectra (molecular cocktail). So far, this approach has not led to higher efficiency cells when compared to the best (single) dye with broad absorption characteristics.

FIG. 2 is partial cross-sectional view depicting a DSC made with two separate layers of photoanode sensitized with different dyes, as described by Chiba et al. in U.S. Pat. No. 6,677,516 (prior art). In this case, one layer of TiO₂ contains magnesium oxide on the surface. Through surface etching, the dye molecules attached on the particles within this porous layer are removed together with the magnesium oxide layer, which can subsequently be replaced by another type of dye molecule(s). Although both the absorption spectrum and output current are improved, the output voltage is still limited to the TiO₂—electrolyte energy level alignment. As a result, the overall output efficiency is still lower than the 11% obtained using single dye system.

FIG. 3 is a partial cross-sectional view of a DSC where two photoanode layers are independently fabricated on separate substrates and then combined together (prior art). The first cell contains the first paste and the first dye fabricated on a substrate while, separately, a second cell containing a second paste and second dye is fabricated on a second substrate. Next, the two cells as bonded together by using a sealing agent in a manner such that they oppose each other with a platinum mesh or a platinum coated carbon mesh between them. An iodine charge transport layer is deposited between the two electrode pastes. Electrically, the two solar cells are connected in parallel, so the output voltage is ultimately controlled by the lower one, while the output current is the sum of the two. Since the electrolyte is the same and the electrode pastes have similar band structures, the output voltages of the two cells are very similar. The challenges of this cell are: (a) the middle electrode (cathode) has to be transparent in order to allow light to penetrate to the bottom cell, and (b) an effective connection of the three external electrodes (two anodes, one cathode) in a small area.

FIG. 4 is a partial cross-sectional view depicting two DSC cells stacked together (prior art). The DSC cells are fabricated separately, and both are sealed before being brought together. The two cells can be connected either in parallel or in series. The challenges for this cell are similar to the previous structure: (a) the Pt has to be thin to be semi-transparent, and (b) the electrical connection cannot occupy too much of the area. In addition to these challenges, the cost of this cell is basically 2 times higher than the single cell.

FIG. 5 is a schematic drawings of a tandem DSC structure with two external electrodes and its corresponding band diagram and charge flow (prior art). The first semiconductor electrode functions as a hole transport material and the second as an electron transport material, whereby the two potential differences between the redox potential of the electrolyte and the two active electrodes sum up to the photovoltage. The photocathode is made of NiO nanoparticles for hole conduction and the photoanode is made of nanoparticle TiO₂ for electron conduction. The electrolyte functions as the electrical connection for the two DSC cells. The difference between this cell and the previous two tandem cell examples is that no Pt electrode is needed between the two cells. In the previous two examples the two nanoparticle electrodes are photoanodes. The challenges of this cell are (1) the current generated in these two cells has to match well in order to obtain the maximum output current since the two cells are connected in series, and (2) the voltage output is, limited because the electrolyte is used to connect these two cells. For the example shown in FIG. 5, the NiO cell produces a voltage output of ˜0.2V.

It would be advantageous if a transfer and bond technology could be used to construct a high efficiency tandem DSC cell.

### SUMMARY OF THE INVENTION

Described herein is a “double anodization” process used to produce a robust layer of TNT from an anodized Ti foil. While other documented “transfer” techniques involve transferring thin, freestanding unannealed TNT membranes that are very fragile and prone to breaking/cracking, the double anodization process described herein results in large-area films which remains strong enough to withstand transfer/handling. The TNT film is produced by anodizing a polished Ti foil in a fluoride ion-containing electrolyte; this initial anodization produces the principal TNT layer of interest. In one aspect, the foil is removed from electrolyte, dried, and then annealed at a temperature of about 450° C. to 600° C. to transform the TNT to anatase phase. The foil is then anodized again for a short period of time to form an underlying amorphous TNT layer, which can be etched in an H₂O₂ solution. With optimal etch conditions, the entire TNT layer can be removed from the foil with little/no cracking or breakage. The resultant crystallized TNT film is quite robust compared to nonannealed, amorphous TNT. The freestanding crystallized film also exhibits relatively little curvature/stress, allowing ease of handling for future processes. The TNT layer can then applied to a secondary substrate coated with a medium, which ultimately forms a transparent conductive adhesion layer.

Accordingly, a method is provided for forming a tandem dye-sensitized solar cell (DSC) using a bonding process. The method forms a first photovoltaic (PV) cell including a cathode, a first dye, and an anode. A second PV cell is also formed including a cathode, a second dye, and an anode. The second PV cell anode is bonded to the first PV cell cathode, at a temperature of less than 100 degrees C., using a transparent conductive adhesive. In response to the bonding, an internal series electrical connection is formed between the first PV cell and the second PV cell.

In one aspect, the second PV cell is formed from a first titanium oxide (TiO₂) nanotube (TNT) layer anode. The first PV cell is formed from a second TNT layer anode. The first dye is deposited overlying the second TNT layer anode, and a first solid state hole conductor cathode overlies the first dye. Likewise, the second PV cell is formed by depositing the second dye overlying the first TNT layer anode, and forming a second solid state hole conductor cathode overlying the second dye. Thus, the bonding of the first TNT layer to the first PV cell cathode includes the first transparent conductive adhesive forming an internal series electrical connection between the first TNT layer anode and the first solid state hole conductor cathode.

Additional details of the above-described method, a tandem DSC, and a method for fabrication TNT are provided below.

### BRIEF DESCRIPTION OF THE DRAWINGS

FIG. 1 is a partial cross-sectional view of typical DSC structure (prior art).

FIG. 2 is partial cross-sectional view depicting a DSC made with two separate layers of photoanode sensitized with different dyes, as described by Chiba et al. in U.S. Pat. No. 6,677,516 (prior art).

FIG. 3 is a partial cross-sectional view of a DSC where two photoanode layers are independently fabricated on separate substrates and then combined together (prior art).

FIG. 4 is a partial cross-sectional view depicting two DSC cells stacked together (prior art).

FIG. 5 is a schematic drawings of a tandem DSC structure with two external electrodes and its corresponding band diagram and charge flow (prior art).

FIG. 6 is a partial cross-sectional view of a tandem dye-sensitized solar cell (DSC).

FIG. 7 is a partial cross-sectional view depicting a first variation of the tandem DSC of FIG. 6.

FIG. 8 is a partial cross-sectional view depicting a second variation of the tandem DSC of FIG. 6.

FIG. 9 is a partial cross-sectional view depicting a third variation of the tandem DC of FIG. 6.

FIG. 10 is a partial cross-sectional view depicting a fourth variation of the tandem DC of FIG. 6.

FIG. 11 is a partial cross-sectional view depicting a fifth variation of the tandem DC of FIG. 6.

FIGS. 12A through 12F depict steps in the fabrication of a TNT film.

FIG. 13 is a cross-sectional view depicting the tandem DSC of FIG. 7, with the TNT layers shown in greater detail.

FIG. 14 is a partial cross-sectional view alternatively depicting the tandem DSC of FIG. 8.

FIG. 15 is a partial cross-sectional view alternatively depicting the tandem DSC of FIG. 9.

FIG. 16 is a flowchart illustrating a method for forming a tandem DSC using a bonding process.

FIG. 17 is a flowchart illustrating a method for forming a TNT film.

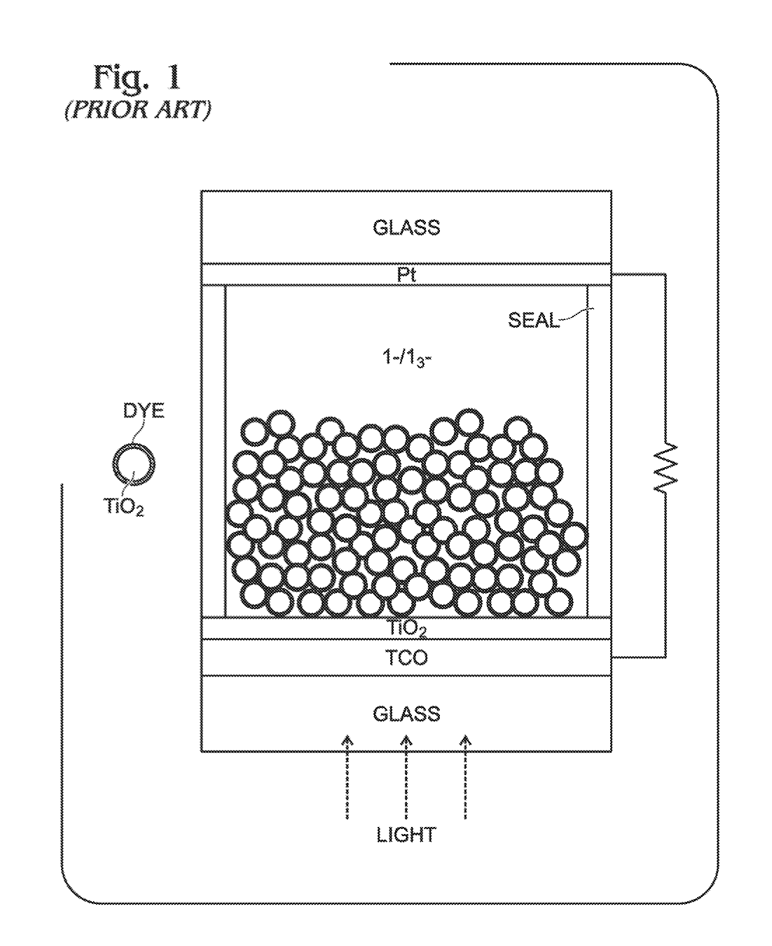

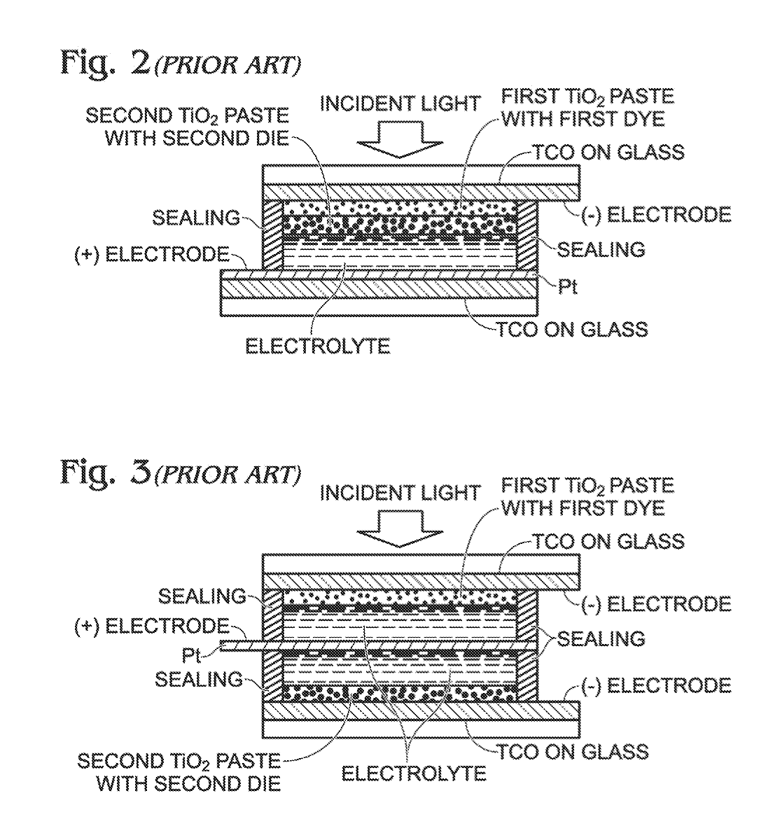

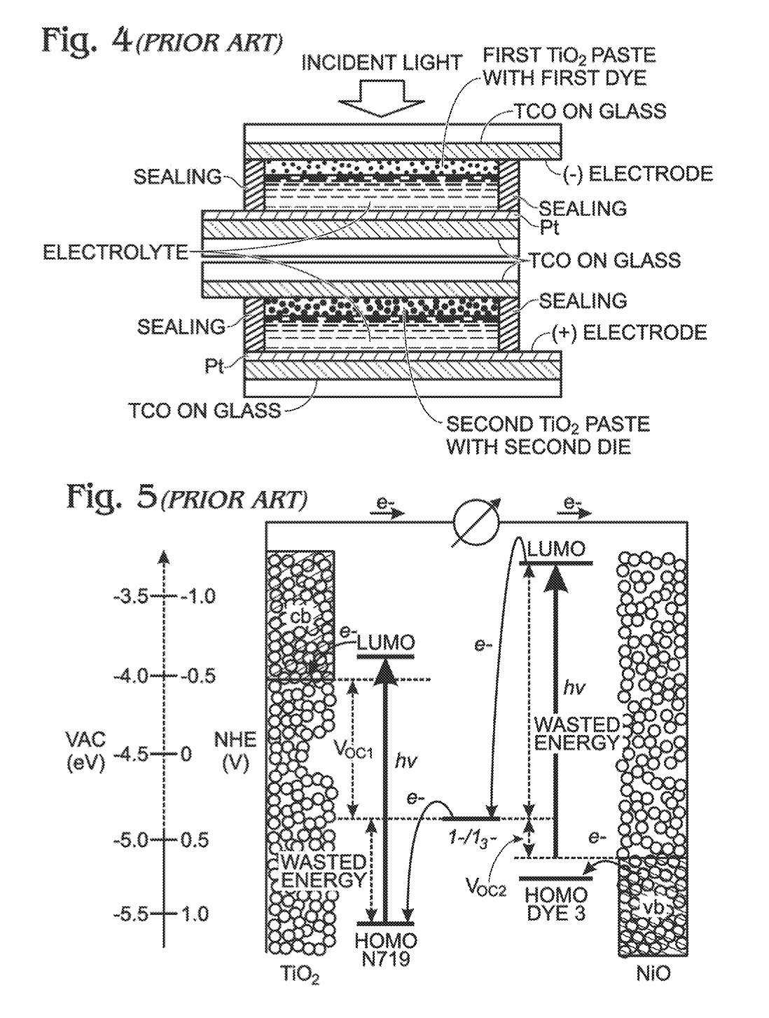

### DETAILED DESCRIPTION

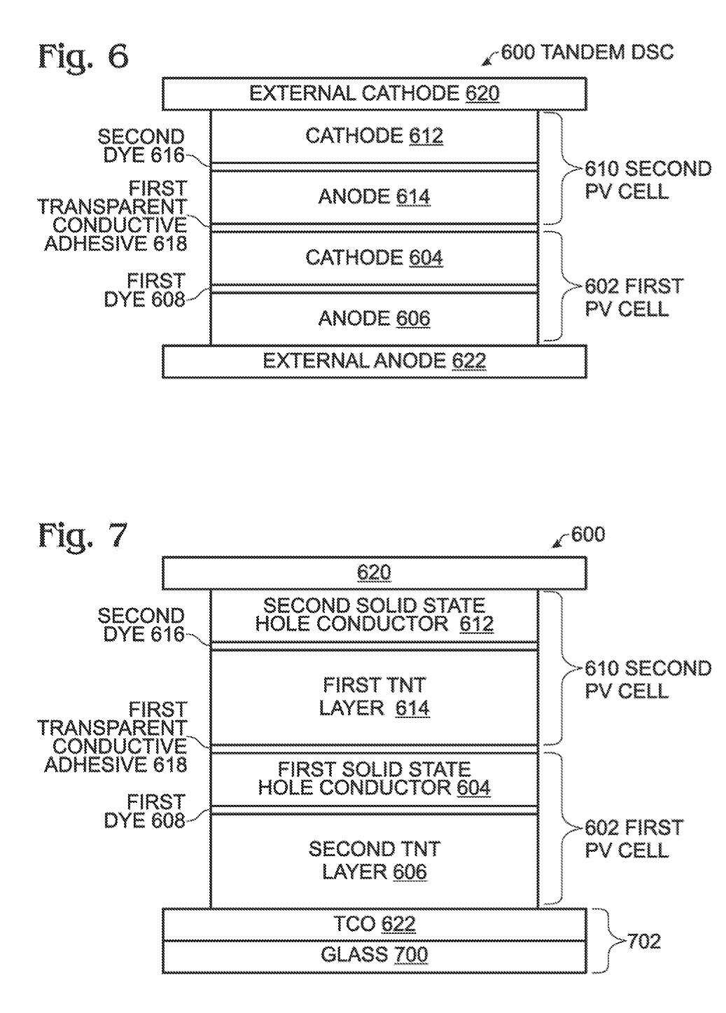

FIG. 6 is a partial cross-sectional view of a tandem dye-sensitized solar cell (DSC). The tandem DSC 600 comprises a first photovoltaic (PV) cell 602 including a cathode 604, an anode 606, and a first dye 608 interposed between the anode 606 and cathode 604. A second PV cell 610 includes a cathode 612, an anode 614, and a second dye interposed 616 between the anode 614 and cathode 612. A first transparent conductive adhesive 618 bonds the second PV cell anode 614 to the first PV cell cathode 604, forming an internal series electrical connection between the first PV cell 602 and the second PV cell 610. In one aspect, the second PV cell anode 614 is a first titanium oxide (TiO₂) nanotube (TNT) layer. A first external electrode (external cathode) 620 overlies the second PV cell cathode 612, and a transparent second external electrode (external anode) 622 underlies the first PV cell anode 606. Some examples of the first transparent conductive adhesive include organic adhesives such as: poly(3,4-ethylenedioxythiophene):poly(styrene sulfonate) (PEDOT:PSS) or similar polymers based upon the PEDOT scaffolding such as Aedotron™ and Oligitron™ (TDA Research, Inc.), polythiophene derivatives, polyaniline, polypyrrole, polyacetylene, polyphenylenevinylene, polyphenylene sulfides, etc., which may contain other additives to increase conductivity and/or adhesion properties. Also included are otherwise nonconductive or low conductivity adhesive polymers that are appropriately doped with metals, metal nanoparticles, carbon nanotubes, etc., in order to increase conductivity.

FIG. 7 is a partial cross-sectional view depicting a first variation of the tandem DSC of FIG. 6. In this aspect, the first PV cell anode 606 is a second TNT layer and the cathode 604 is a first solid state hole conductor overlying the first dye 608. The second PV cell cathode 612 is a second solid state hole conductor cathode overlying the second dye 616, and the anode 614 is the first TNT layer. The bond 618 between the first TNT layer 614 and the first PV cell cathode 604 forms the internal series electrical connection between the first PV cell 602 and the second PV cell 610. The second external electrode (external anode) 622 is a transparent conductive oxide (TCO) layer overlying a glass layer 700, which is referred to herein as a TCO layer/glass stack 702 underlying the second TNT layer 606. The TCO layer 622 may be about 0.2 um to 1.0 um thick and the glass 700 may be about 0.5 to 3 mm thick. The TCO layer can be selected from the following materials: SnO₂:F (FTO), In₂O₃—SnO₂ (ITO), ZnO, ZnO:Al(Ga), carbon nanotube layer and graphene layer. Typically, the TCO/glass stack 702 is formed prior to any device integration.

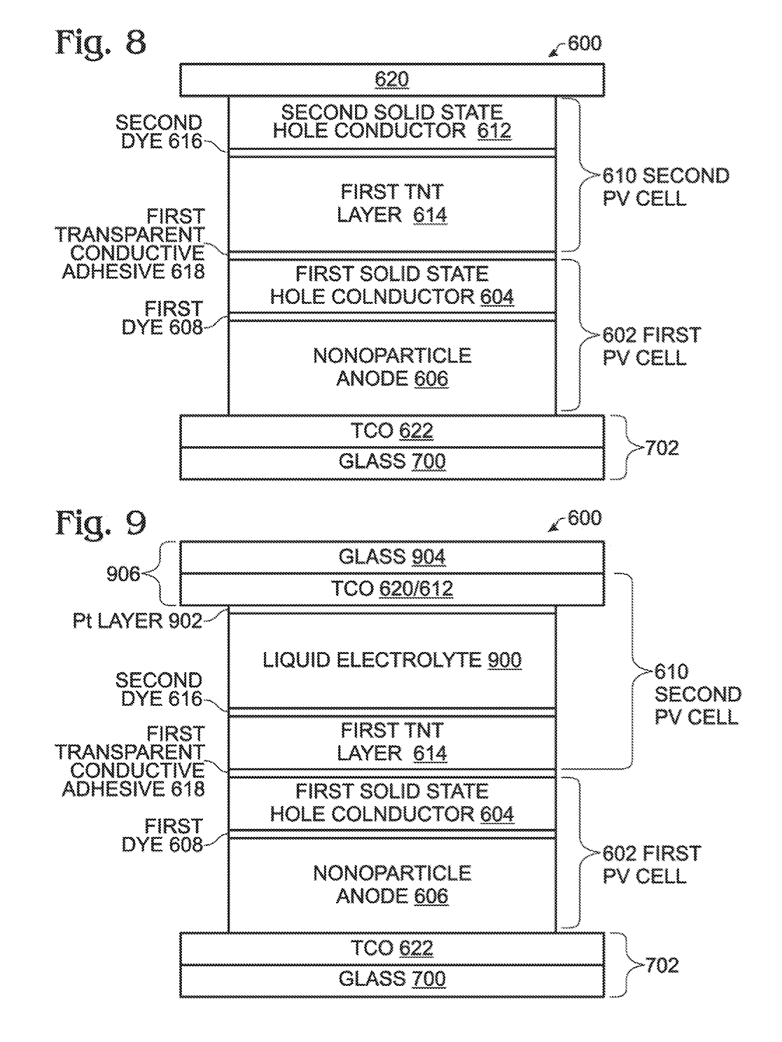

FIG. 8 is a partial cross-sectional view depicting a second variation of the tandem DSC of FIG. 6. As is FIG. 7, the second external electrode (external anode) 622 is a TCO layer/glass stack 702. The first PV cell anode 606 is a nanoparticle anode, with particles such as TiO₂, SnO₂, and ZnO overlying the TCO layer/glass stack 702. The cathode 604 is the first solid state hole conductor overlying the first dye 608. The second PV cell cathode 612 is the second solid state hole conductor overlying the second dye 616, and the anode 614 is the first TNT layer.

FIG. 9 is a partial cross-sectional view depicting a third variation of the tandem DC of FIG. 6. In this aspect the second PV cell 610 includes a liquid electrolyte 900 including iodine and tri-iodine overlying the first TNT layer/second dye 614/616. A platinum (Pt) layer 902 overlies the liquid electrolyte 900. In this aspect, external cathode 620 also acts as the second PV cell cathode 612. The first external electrode (external cathode) 620 overlying the second PV cell 610 is a TCO layer with an overlying layer of glass 904, which is referred to herein as a glass/TCO layer stack 906 overlying the Pt layer 902. Typically, the TCO/glass stack 906 is formed prior to any device integration. Pt then is deposited on TCO/glass to form a plate that is used later as the first external electrode 620.

The second external electrode (external anode) 622 is a TCO layer/glass stack 702. The first PV cell anode 606 is a nanoparticle anode, with particles such as TiO₂, SnO₂, and ZnO, overlying the TCO layer/glass stack 702. The cathode 604 is the first solid state hole conductor overlying the first dye 608.

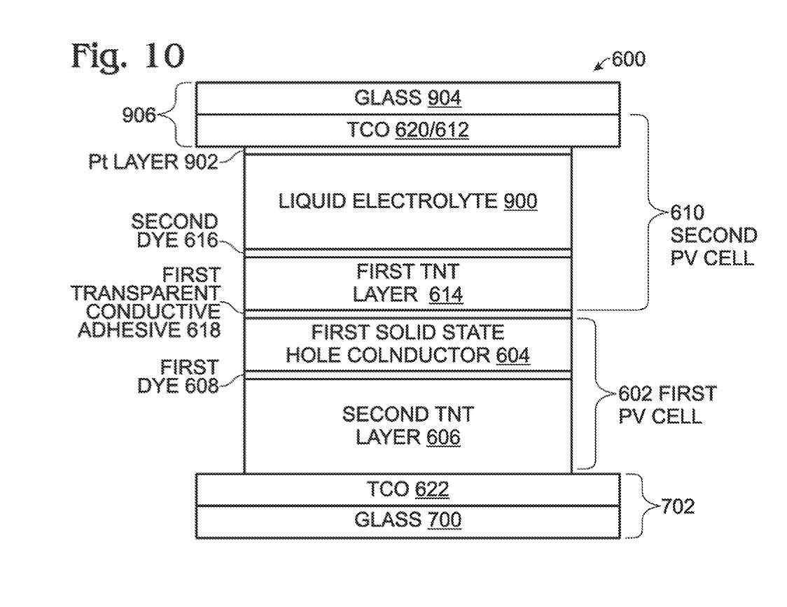

FIG. 10 is a partial cross-sectional view depicting a fourth variation of the tandem DC of FIG. 6. As in FIG. 9, the second PV cell 610 includes a liquid electrolyte 900 including iodine and tri-iodine overlying the first TNT layer/second dye 614/616. A Pt layer 902 overlies the liquid electrolyte 900. The first external electrode (external cathode) 620 overlying the second PV cell 610 is a glass/TCO layer stack 906 overlying the Pt layer 902. The second external electrode (external anode) 622 is a TCO layer/glass stack 702. The first PV cell anode 606 is a second TNT layer and the cathode 604 is a first solid state hole conductor overlying the first dye 608.

Conventional solar cells can be made from TNT using a structure such as: glass/TCO/Pt/electrolyte/TNT/Ti, where the light enters from the glass side. The Pt is necessary to reduce oxidized tri-iodine, and since its thickness is in the range, of 3 nm to 10 nm, it blocks light. The two electrodes are Ti and TCO. In order not to block the light, a single cell structure must be built with the following structure: glass1/TCO/Pt/electrolyte/TNT/TCO/glass2. The light enters from the glass 2 side. The TNT has to be on the TCO/glass. However, since the TNT layer is very thick, there is no way to make a Ti/TCO/glass substrate and then anodize the Ti to form the TNT/TCO/glass. This is the reason that a transfer and bond process must be used to bond TNT to TCO/glass.

FIG. 11 is a partial cross-sectional view depicting a fifth variation of the tandem DC of FIG. 6. The basic structure of FIG. 6 is not limited to any particular number of tandem cells. To represent additional tandem PV cells an nth PV cell 1100 is shown, where n is an integer variable greater than 2. The nth PV cell 1100 includes an nth TNT layer anode 1102, a cathode 1104, and an nth dye 1106 interposed between the anode 1102 and cathode 1104. A second transparent conductive adhesive 1108 bonds the nth TNT layer 1102 to the second PV cell cathode 612, forming an internal series electrical connection between the second PV cell 610 and the nth PV cell 1100.

### Functional Description

The TNT fabrication process, described in more detail below, provides a low-cost process for producing large areas of TNT for use in the fabrication of DSCs. The TNT layer can be formed on large-area Ti foils, the size of which is only limited by equipment and/or electrolyte volumes used. The anodization process also allows for transfer of robust, large-area, stress-free films of TNT (from the Ti substrate). While other researchers have transferred freestanding TNT membranes, the inherent fragility of the unannealed membrane limits the ultimate size of the DSC. Finally, the high-quality bond between the TNT and the secondary substrate allows for effective ultrasonic removal of surface residue deposited onto the TNT layer during anodization.

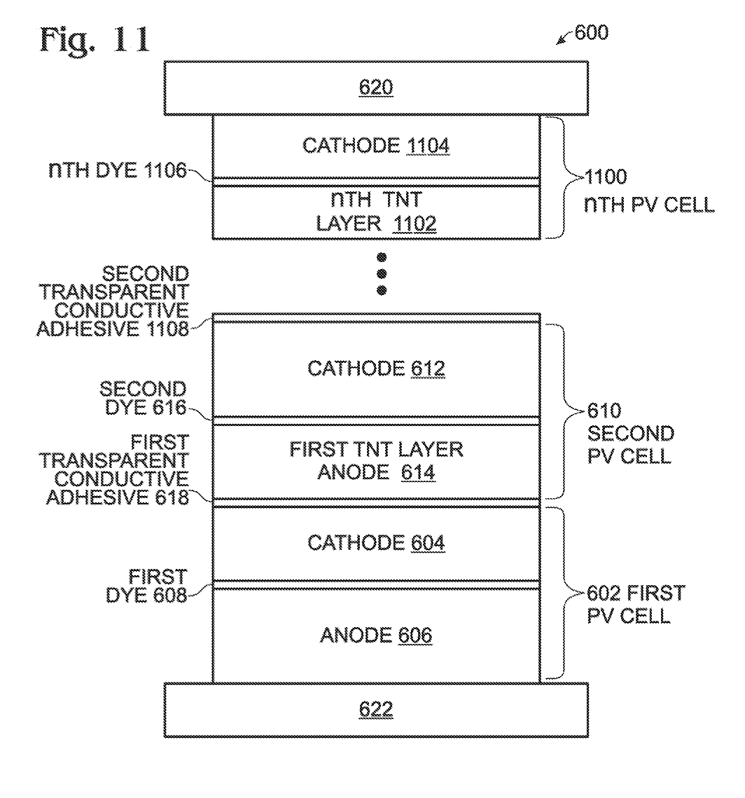

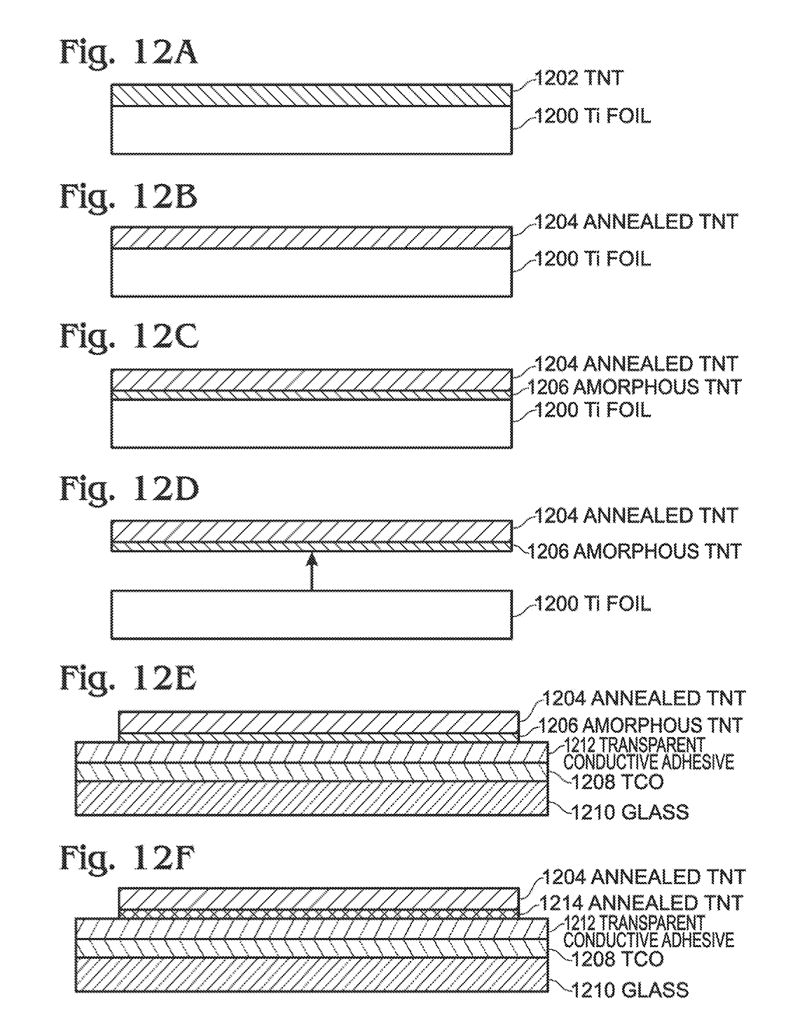

FIGS. 12A through 12F depict steps in the fabrication of a TNT film. In FIG. 12A, Ti foil 1200 is anodized in a fluoride-ion containing electrolyte to form a TNT layer 1202 on the surface of the Ti foil. The nanotube morphology (e.g., tube diameter and tube length) is dependent upon the electrolyte composition/concentration, anodization voltage, bath temperature, PH value, and anodization time. Typically, the TNT 1202 has a thickness of 10-30 um, consuming 10-30 um of the Ti layer 1200.

In FIG. 12B the TNT/foil 1202/1200 is annealed to convert the TNT from amorphous to anatase phase TNT 1204. In FIG. 12C a second, shorter anodization is performed, producing an amorphous TNT layer 1206 underneath the now-annealed TNT film 1204. In FIG. 12D the TNT/foil 1204/1206/1200 is immersed in an H₂O₂ solution, which etches the amorphous TNT layer 1206 and induces liftoff of the film 1204 from the foil 1200. In FIG. 12E the freestanding TNT film 1204/1206 is then bonded to a secondary glass/TCO 1210/1208 substrate with a transparent conductive adhesive 1212. For example, the TCO layer can be selected from the following materials: SnO₂:F (FTO), In₂O₃—SnO₂ (ITO), ZnO, ZnO:Al(Ga), carbon nanotube layer, and grapheme layer. In FIG. 12F the bonded sample 1204/1206 is annealed again to cure the adhesive 1212. In this example, the second anneal also converts the underlying, amorphous

TNT to anatase form 1212.

One aspect involves an adhesive 1212 titanium bearing precursor material such as titanium acetate or titanium isopropoxide that can be applied to bond the TNT later to the TCO/glass, and which is subsequently converted into titanium dioxide (anatase) by means of suitable heat treatment. Alternatively, a composite precursor consisting of a titanium dioxide colloidal suspension (nanoparticles suspended in a liquid medium) might be used such that the subsequent heat treatment consolidates and sinters the colloidal particles with the TNT's to form an aggregate adherent layer. Thirdly, heteromaterials such as conductive polymers (for example PEDOT:PSS—poly(3,4-ethylenedioxythiophene):poly(styrene sulfonate)) might be used instead of a titanium bearing precursor.

During the bonding process, pressure is applied to the TNT layer and the substrate is heated so as to cure the adhesive. This bonding process may be carried out with a “stamping” tool which applies uniform pressure to the tape/TNT layer. Or a wafer bonder may be used to apply compressive force under vacuum in order to minimize any air bubbles at the adhesive/TNT interface.

A “removal medium” (such as thermal-release tape) can be used to remove the TNT layer from Ti foil and “hold” the TNT layer prior to bonding it to a second substrate. The TNT layer (attached to tape) is applied to a secondary substrate coated with a medium. After heating the bonded pair at high temperature ˜100° C.-200° C., the thermal tape and the TNT are separated, leaving the TNT layer bonded to the second substrate coated with a medium, which ultimately forms a transparent conductive adhesion layer. After bonding to the second substrate, the sample can be placed in an ultrasonic bath to remove surface residue from the tops of the nanotubes. The bond is strong enough to keep the TNT attached to the substrate while the residue is removed with the ultrasonic agitation.

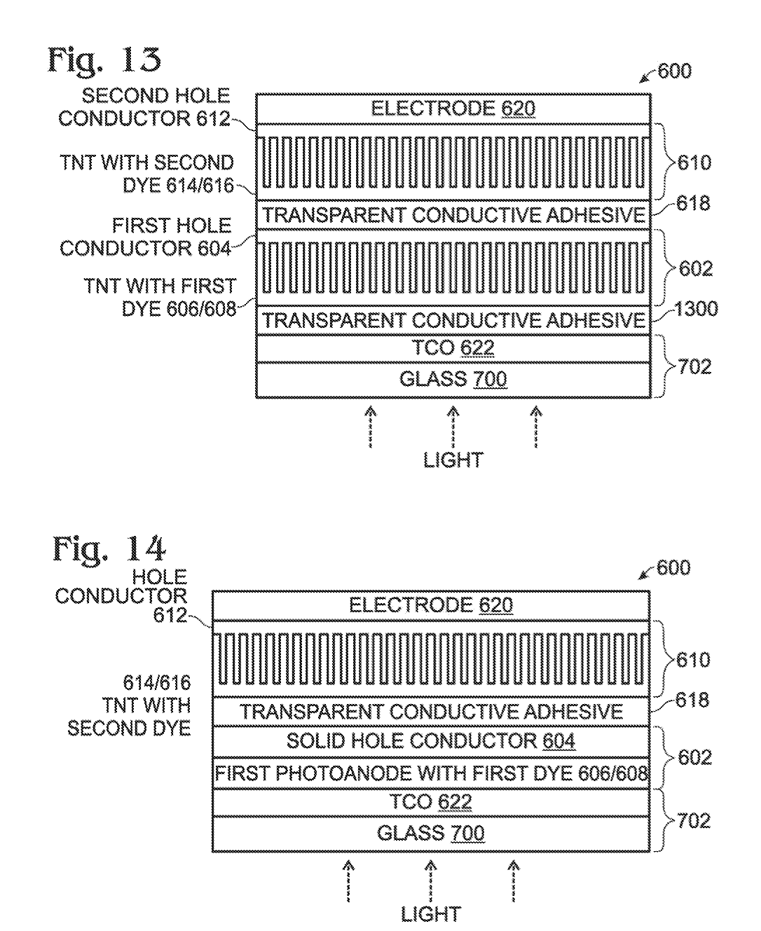

FIG. 13 is a cross-sectional view depicting the tandem DSC of FIG. 7, with the TNT layers shown in greater detail. Transfer and bond technology is used to stack up the solar cell to make a tandem junction cell. As shown, the second TNT layer 606 is transferred to a TCO/glass stack 702 using a transparent conductive adhesive 1300. Transparent conductive adhesive 1300 can be either a low temperature organic adhesive, such as adhesive 618, or a high temperature adhesive. Some examples of the low temperature organic adhesives include conductive polymers such as PEDOT:PSS—poly(3,4-ethylenedioxythiophene):poly(styrene sulfonate compound. Some examples of high temperature adhesives include titanium bearing precursor materials such as titanium acetate solution, titanium isopropoxide solution and atitanium dioxide colloidal suspension precursor. At this step in the process the structure is TNT/adhesive/TCO/glass, which can withstand temperatures as high as about 500° C. Therefore, the titanium bearing precursor materials can be used in adhesive 1300, but cannot be used in adhesive 618.

The first dye 608 is absorbed to the TNT surface and the first solid state hole conductor 604 is applied on TNT surface which penetrates to the TNT microstructures. Typically, thee nanotubes have one open end and one closed end (on the bottom of TNT layer). The solid state hole conductor can be Spiro-OMeTAD, p-type semiconductors (e.g., CuSCN or CuI), or polymer electrolyte. The first transparent conductive adhesive 618 is then applied to the first solid state hole conductor 604. The first TNT layer 614 may then be transferred onto the first transparent conductive adhesive 618. The second dye 616 is absorbed into the first TNT surface 614 either prior to or after the first TNT layer 614 bonding with the first PV cell 602, and the second solid state hole conductor 612 is applied to the first TNT surface, which similarly penetrates to the TNT microstructures. Alternatively, the second PV cell 610 can be completely assembled prior to bonding with the first PV cell 602. Finally, the metal electrode (cathode) 620 is deposited onto the second hole conductor 612.

In one aspect, the first dye 608 and the second dye 616 exhibit different absorption spectra that are complimentary and cover the solar spectrum. In one aspect the first dye absorbs shorter wavelengths and the second dye absorbs the longer wavelengths. However, since the dye(s) have different absorption spectra, this is not a strict requirement. Although a two-stacked cell is shown, more stacking is possible (see FIG. 11).

Representative classes of dyes for a DSC include metal pyridyl and polypyridyl complexes, indolines, coumarins, hemicyanines, merocyanines, squaraines, porphyrins and metalloporphyrins, chlorophyll and chlorophyll derivatives, natural pigments, chlorins and metallochlorins, phthalocyanines and metallophthalocyanines, naphthalocyanines and metallonaphthalocyanines, azaporphyrins and metalloazaporphyrins, boron-dipyrrins, triphenylamines, pyridiniums, polyenes, polyynes, thiophenes, perylenes (and higher “rylenes”) including dimers, trimers and/or tetramers of each class of materials or of mixed classes of materials, mixtures of two or more members of the same or different classes as well as conjugates and derivatives consisting of various combinations of classes.

FIG. 14 is a partial cross-sectional view alternatively depicting the tandem DSC of FIG. 8. In this example, the first DSC cell 602 is fabricated with a nanoparticle electrode 606. The nanoparticle can be TiO₂, SnO₂, or ZnO, and the photoanode process is well documented. The first dye 608 is absorbed at the surface of the nanoparticle layer, and the first solid hole conductor 604 is applied to the nanoparticle electrode 606 which penetrates to the microstructures. Finally, the transparent conductive adhesive 618 is applied to the first solid state hole conductor 604. The first TNT layer 614 may be transferred onto the transparent conductive adhesive 618. The second dye 616 is absorbed into the TNT surface either prior to or after the first TNT layer 614 bonding with the first PV cell 602, and the second solid state hole conductor 612 is applied to the first TNT surface, penetrating to the TNT microstructures. Alternatively, the second PV cell 610 can be completely assembled prior to bonding with the first PV cell 602. Finally, the metal electrode (cathode) 620 is deposited onto the second hole conductor 612. Again, the first and the second dyes may have different absorption spectra that are complimentary to one another and are capable of absorbing across broad ranges of the solar spectrum. In one aspect the first dye is capable of absorbing shorter wavelengths and the second dye absorbs longer wavelengths. However, since the dye(s) have different absorption spectra, this is not a strict requirement. Additional stacks can be added before the electrode 620 deposition.

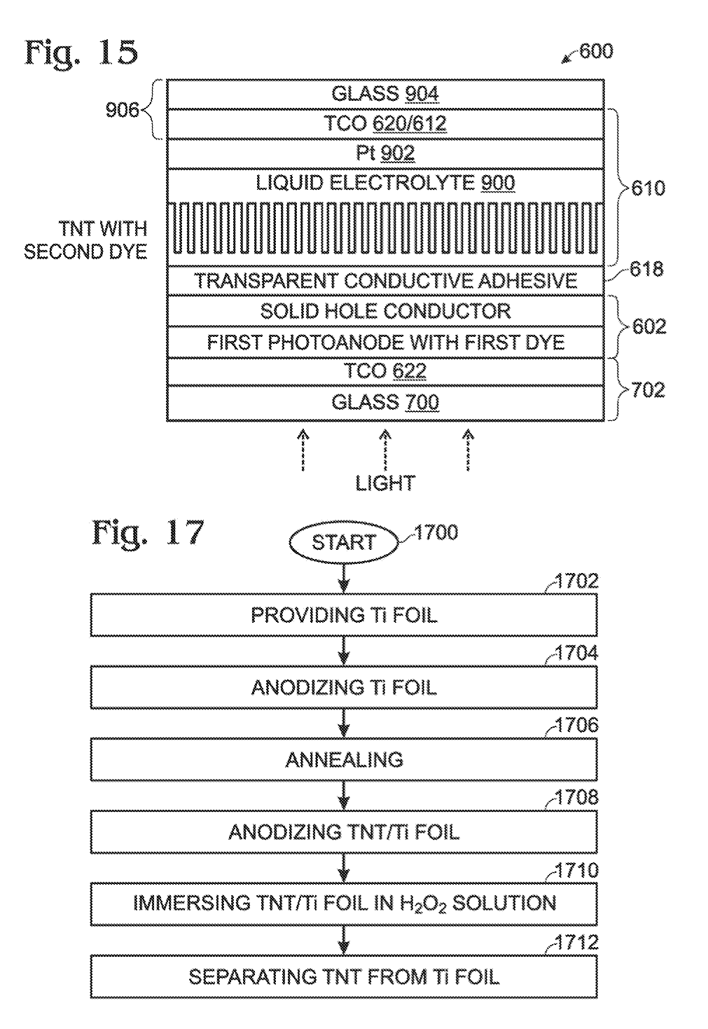

FIG. 15 is a partial cross-sectional view alternatively depicting the tandem DSC of FIG. 9. This structure includes the use of a liquid electrolyte 900 on the final layer for hole conducting. Instead of a solid hole conductor, a liquid electrolyte 900 containing iodine and tri-iodine is used to reduce the oxidized dye. The Pt layer 902 is used as a catalyst to reduce the oxidized tri-iodine (I₃₋+2ₑ₋→3I₋), and the TCO layer 620 reduces the series resistance and serves as an external cathode. The sealing is not shown in the figure.

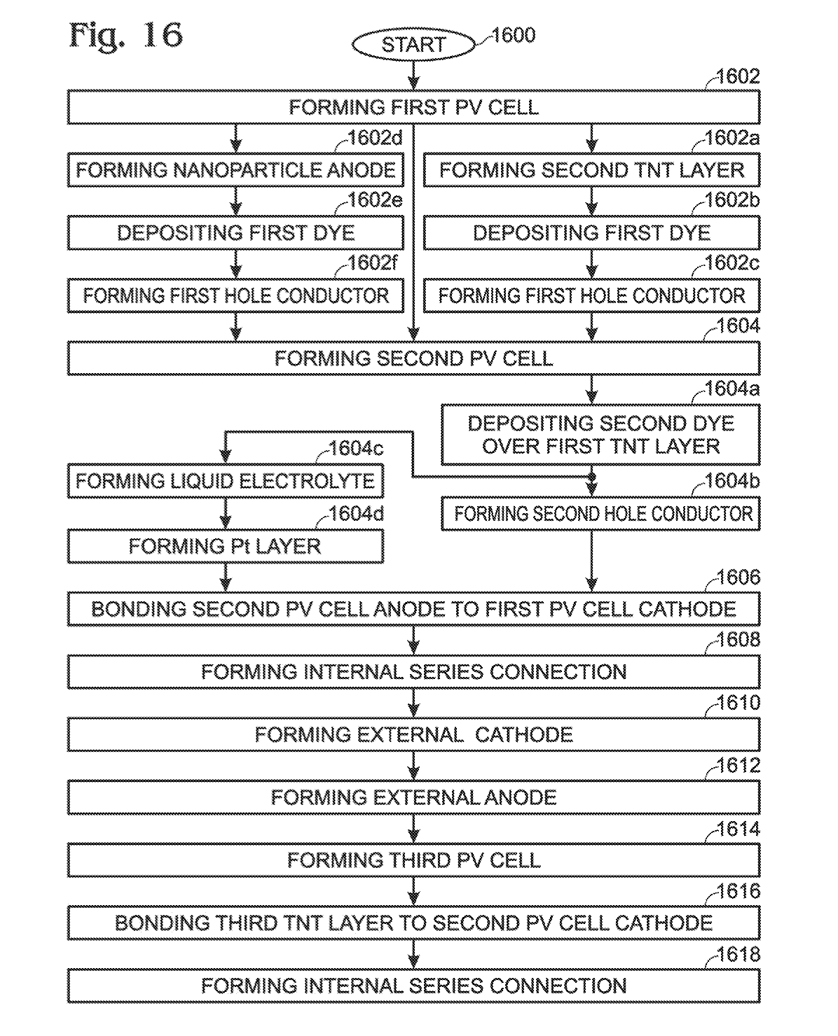

FIG. 16 is a flowchart illustrating a method for forming a tandem DSC using a bonding process. Although the method is depicted as a sequence of numbered steps for clarity, the numbering does not necessarily dictate the order of the process steps. It should be understood that some of these steps may be skipped, performed in parallel, or performed without the requirement of maintaining a strict order of sequence. Generally however, the steps are performed in numerical order. The method starts at Step 1600.

Step 1602 forms a first PV cell including a cathode, a first dye, and an anode. Step 1604 forms a second PV cell including a cathode, a second dye, and an anode. In one aspect, the second PV cell anode is a first TNT layer anode. Step 1606 bonds the second PV cell anode to the first PV cell cathode, at a temperature of less than 100 degrees C., using a first transparent conductive adhesive. In response to the bonding, Step 1608 forms an internal series electrical connection between the first PV cell and the second PV cell. Step 1610 forms a first external electrode (external cathode) overlying the second PV cell cathode. Step 1612 forms a transparent second external electrode (external anode) underlying the first PV cell anode.

In one aspect, forming the first PV cell in Step 1602 includes the following substeps. Step 1602a forms a second TNT layer anode. Step 1602b deposits the first dye overlying the second TNT layer anode. Step 1602c forms a first solid state hole conductor cathode overlying the first dye. Forming the second PV cell in Step 1604 includes the following substeps. Step 1604a deposits the second dye overlying the first TNT layer anode. Step 1604b forms a second solid state hole conductor cathode overlying the second dye. Then, forming the internal series connection in Step 1608 includes the first transparent conductive adhesive forming an internal series electrical connection between the first TNT layer anode and the first solid state hole conductor cathode. In another aspect, forming the first PV cell in Step 1602 includes forming the second TNT layer anode on a TCO layer/glass stack, prior to bonding the first TNT layer to the first PV cell cathode, where the first TCO layer is the second external electrode (external anode). Forming the second TNT layer anode on the TCO layer/glass stack includes bonding the second. TNT layer on the TCO layer/glass stack using a second transparent conductive adhesive.

In one variation, forming the first PV cell in Step 1602 includes depositing the first dye overlying the second TNT layer anode, subsequent to bonding the second TNT layer to the TCO layer/glass stack. Then forming the second PV cell in Step 1604 includes depositing the second dye either prior to, or subsequent to bonding the first TNT layer to the first PV cell cathode. Step 1610 forms the first external electrode subsequent to forming the second solid state hole conductor cathode.

In a different aspect, Step 1602 is performed using the following substeps. Step 1602d forms a nanoparticle anode, with TiO₂, SnO₂, or ZnO particles, overlying a TCO layer/glass stack, where the TCO layer is the second external electrode (external anode). Step 1602e deposits the first dye overlying the nanoparticle anode, and Step 1602f forms a first solid state hole conductor cathode overlying the first dye. Bonding the first TNT layer to the first PV cell cathode in Step 1606 includes bonding the first TNT layer to the first solid state hole conductor cathode subsequent to depositing the first dye, and in Step 1608 the transparent conductive adhesive forms the internal series electrical connection between the first TNT layer and the first solid state hole conductor cathode. In this aspect, forming the second PV cell in Step 1604 includes forming the second PV cell by depositing the second dye overlying the first TNT layer either prior to, or subsequent to bonding the first TNT layer to the first PV cell cathode. Then, a second solid state hole conductor cathode is formed overlying the first TNT layer/second dye.

In a third variation, forming the second PV cell includes forming the second PV as follows. Step 1604a deposits the second dye overlying the first TNT layer either prior to, or subsequent to bonding the first TNT layer to the first PV cell cathode. Step 1604c forms a liquid electrolyte including iodine and tri-iodine overlying the first TNT layer anode. Step 1604d forms a platinum layer overlying the liquid electrolyte. Then, Step 1610 forms the first external electrode (external cathode) form a glass/TCO layer stack overlying the Pt layer.

The first PV cell is formed as described in Steps 1602d through 1602f, above. Alternatively, the first PV cell is formed performing Steps 1662a through 1602c.

In another aspect, Step 1614 forms a third PV cell including a third TNT layer anode, a third dye, and a cathode. Step 1616 bonds the third TNT layer to the second PV cell cathode with the first transparent conductive adhesive at a temperature of less than 100 degrees C. In response to the bonding, Step 1618 forms an internal series electrical connection between the second PV cell and the third PV cell. As noted above, the tandem DSC is not limited to any particular number of stacked PV cells.

FIG. 17 is a flowchart illustrating a method for forming a TNT film. The method of FIG. 17 could be used to enable Steps 1602 and 1606 of FIG. 16. The method starts at Step 1700. Step 1702 provides a Ti foil. The Ti foil may have a thickness in the range 10-500 um. Step 1704 anodizes the Ti foil in a fluoride-ion containing electrolyte for a first period of time (e.g., (10 min to 10 hrs), forming an amorphous TNT material (e.g., 2-30 um thick) overlying the Ti foil. Step 1706 anneals (e.g., 400 to 500° C.) the TNT/Ti foil, forming anatase phase TNT. Step 1708 anodizes the TNT/Ti foil for a second period of time (e.g., 30 second to 1 hr), less than the first period, forming an amorphous TNT layer interposed between an annealed top TNT layer and the Ti foil. Step 1710 immerses the TNT/Ti foil in an H₂O₂ solution, etching the amorphous TNT layer. Step 1712 separates the TNT from the Ti foil.

A tandem DSC device and associated fabrication processes have been provided. Particular materials, device structures, and process details have been presented as examples to illustrate the invention. However, the invention is not limited to just these examples. Other variations and embodiments of the invention will occur to those skilled in the art.

We claim:

1. A method for forming a tandem dye-sensitized solar cell (DSC) using a bonding process, the method comprising:
forming a first photovoltaic (PV) cell including a cathode, a first dye, and an anode;
forming a second PV cell including a cathode, a second dye, and an anode;
bonding the second PV cell anode to the first PV cell cathode, at a temperature of less than 100 degrees C., using a first transparent conductive adhesive; and,
in response to the bonding, forming an internal series electrical connection between the first PV cell and the second PV cell.

2. The method of claim 1 wherein forming the second PV cell includes forming a first titanium oxide (TiO₂) nanotube (TNT) layer anode.

3. The method of claim 2 further comprising:
forming a first external electrode (external cathode) overlying the second PV cell cathode; and,
forming a transparent second external electrode (external anode) underlying the first PV cell anode.

4. The method of claim 3 wherein forming the first PV cell includes forming the first PV cell as follows:
forming a second TNT layer anode;
depositing the first dye overlying the second TNT layer anode;
forming a first solid state hole conductor cathode overlying the first dye; and,
wherein forming the second PV cell includes:
depositing the second dye overlying the first TNT layer anode;
forming a second solid state hole conductor cathode overlying the second dye;
wherein forming the internal series connection includes the first transparent conductive adhesive forming an internal series electrical connection between the first TNT layer anode and the first solid state hole conductor cathode.

5. The method of claim 4 wherein forming the first PV cell includes forming the second TNT layer anode on a transparent conductive oxide (TCO) layer/glass stack, prior to bonding the first TNT layer to the first PV cell cathode, where the first TCO layer is the second external electrode (external anode).

6. The method of claim 5 wherein forming the second TNT layer anode on the TCO layer/glass stack includes bonding the second TNT layer on the TCO layer/glass stack using a second transparent conductive adhesive.

7. The method of claim 5 wherein forming the first PV cell includes depositing the first dye overlying the second TNT layer anode, subsequent to bonding the second TNT layer to the TCO layer/glass stack;
wherein forming the second PV cell includes depositing the second dye in a process selected from a group consisting of subsequent to bonding the first TNT layer to the first PV cell cathode, and prior to bonding the first TNT layer to the first PV cell cathode; and,
wherein forming the first external electrode (external cathode) overlying the second PV cell includes forming the first external electrode subsequent to forming the second solid state hole conductor cathode.

8. The method of claim 3 wherein forming the first PV cell includes forming the first PV call as follows:
forming a nanoparticle anode, with particles selected from a group consisting of TiO₂, SnO₂, and ZnO, overlying a TCO layer/glass stack, where the TCO layer is the second external electrode (external anode);
depositing the first dye overlying the nanoparticle anode;
forming a first solid state hole conductor cathode overlying the first dye.

9. The method of claim 8 wherein bonding the first TNT layer to the first PV cell cathode includes bonding the first TNT layer to the first solid state hole conductor cathode subsequent to depositing the first dye; and,
wherein forming the internal series connection includes the transparent conductive adhesive forming the internal series electrical connection between the first TNT layer and the first solid state hole conductor cathode.

10. The method of claim 8 wherein forming the second PV cell includes forming the second PV cell by depositing the second dye overlying the first TNT layer in a process selected from a group consisting of subsequent to bonding the first TNT layer to the first PV cell cathode and prior to bonding the first TNT layer to the first PV cell cathode, and forming a second solid state hole conductor cathode overlying the first TNT layer.

11. The method of claim 3 wherein forming the second PV cell includes forming the second PV cell as follows:
depositing the second dye overlying the first TNT layer in a process selected from a group consisting of subsequent to bonding the first TNT layer to the first PV cell cathode and prior to bonding the first TNT layer to the first PV cell cathode;
forming a liquid electrolyte including iodine and tri-iodine overlying the first TNT layer anode;
forming a platinum (Pt) layer overlying the liquid electrolyte; and,
wherein forming the first external electrode. (external cathode) overlying the second PV cell includes forming a glass/TCO layer stack overlying the Pt layer.

12. The method of claim 11 wherein forming the first PV cell includes forming the first PV cell as follows:
forming a nanoparticle anode, with particles selected from a group consisting of TiO₂, SnO₂, and ZnO, overlying a TCO layer/glass stack, where the TCO layer is the second external electrode (external anode);
depositing the first dye overlying the nanoparticle anode;
forming a first second solid state hole conductor cathode overlying the first dye.

13. The method of claim 11 wherein forming the first PV cell includes forming the first PV cell as follows:
forming a second TNT layer anode;
depositing the first dye overlying the second TNT layer anode; and,
forming a first solid state hole conductor cathode overlying the first dye.

14. The method of claim 2 further comprising:
forming a third PV cell including a third TNT layer anode, a third dye, and a cathode;
bonding the third TNT layer to the second PV cell cathode with the first transparent conductive adhesive at a temperature of less than 100 degrees C.; and,
in response to the bonding, forming an internal series electrical connection between the second PV cell and the third PV cell.

15. The method of claim 2 wherein forming the first TNT layer anode includes;
providing a Ti foil;
anodizing the Ti foil in a fluoride-ion containing electrolyte for a first period of time, forming an amorphous TNT material overlying the Ti foil;
annealing the TNT/Ti foil, forming anatase phase TNT;
anodizing the TNT/Ti foil for a second period of time, less than the first period, forming an amorphous TNT layer interposed between an annealed top TNT layer and the Ti foil;
immersing the TNT/Ti foil in an H₂O₂ solution, etching the amorphous TNT layer; and,
separating the TNT from the Ti foil.

16. A tandem dye-sensitized solar cell. (DSC) comprising:
a first photovoltaic (PV) cell including:
a cathode;
an anode; and,
a first dye interposed between the anode and cathode;
a second PV cell including:
a cathode;
an anode; and,
a second dye interposed between the anode and cathode;
a first transparent conductive adhesive bonding the second PV cell anode to the first PV cell cathode, forming an internal series electrical connection between the first PV cell and the second PV cell.

17. The tandem. DSC of claim 16 wherein the second PV cell anode is a first titanium oxide (TiO₂) nanotube (TNT) layer.

18. The tandem DSC of claim 17 further comprising:
a first external electrode (external cathode) overlying the second PV cell cathode; and,
a transparent second external electrode (external anode) underlying the first PV cell anode.

19. The tandem DSC of claim 18 wherein the first PV cell anode is a second TNT layer and the cathode is a first solid state hole conductor overlying the first dye; and,
wherein the second PV cell cathode is a second solid state hole conductor cathode overlying the second dye; and,
wherein the bond between the first TNT layer and the second PV cell cathode forms the internal series electrical connection between the first PV cell and the second PV cell.

20. The tandem DSC of claim 19 wherein the second external electrode (external anode) is a transparent conductive oxide (TCO) layer/glass stack underlying the second TNT layer.

21. The tandem DSC of claim 18 wherein the second external electrode (external anode) is a TCO layer/glass stack;
wherein the first PV cell anode is a nanoparticle anode, with particles selected from a group consisting of TiO₂, SnO₂, and ZnO overlying the TCO layer/glass stack, and the cathode is a first solid state hole conductor overlying the first dye; and,
wherein the, second PV cell cathode is a second solid state hole conductor overlying the second dye.

22. The tandem DSC of claim 18 wherein the second PV cell includes:
a liquid electrolyte including iodine and tri-iodine overlying the first TNT layer;
a platinum (Pt) layer overlying the liquid electrolyte; and,
wherein the first external electrode (external cathode) overlying the second PV cell is a glass/TCO layer stack overlying the Pt layer;
wherein the second external electrode (external anode) is a TCO layer/glass stack; and,
wherein the first PV cell anode is a nanoparticle anode, with particles selected from a group consisting of TiO₂, SnO₂, and ZnO, overlying the TCO layer/glass stack, and the cathode is a first solid state hole conductor overlying the first dye.

23. The tandem DSC of claim 18 wherein the second PV cell includes:
a liquid electrolyte including iodine and tri-iodine overlying the first TNT layer;
a Pt layer overlying the liquid electrolyte; and,
wherein the first external electrode (external cathode) overlying the second PV cell is a glass/TCO layer stack overlying the Pt layer;
wherein the second external electrode (external anode) is a TCO layer/glass stack; and,
wherein the first PV cell anode is a second TNT layer and the cathode is a first solid state hole conductor overlying the first dye.

24. The tandem DSC of claim 17 further comprising:
a third PV cell including:
a third TNT layer anode;
a cathode; and,
a third dye interposed between the anode and cathode;
a second transparent conductive adhesive bonding the third TNT layer to the second PV cell cathode, forming an internal series electrical connection between the second PV cell and the third PV cell.

25. The method for forming a titanium oxide (TiO₂) nanotube (TNT) film, the method comprising:
providing a Ti foil;
anodizing the Ti foil in a fluoride-ion containing electrolyte for a first period of time, forming an amorphous TNT material overlying the Ti foil;
annealing the TNT/Ti foil, forming anatase phase TNT;
anodizing the TNT/Ti foil for a second period of time, less than the first period, forming an amorphous TNT layer interposed between an annealed top TNT layer and the Ti foil;
immersing the TNT/Ti foil in an H₂O₂ solution, etching the amorphous TNT layer; and,
separating the TNT from the Ti foil.
